(19) United States
(12) Patent Application Publication
(10) Pub. No.: US 2012/0167960 A1
(43) Pub. Date: Jul. 5, 2012

(54) System and Method for Supporting a Plurality of Arrays of Photovoltaic Devices Above a Ground Surface

(75) Inventors: John SCORSONE, Philadelphia, PA (US); John DOLCEAMORE, Drexel Hill, PA (US); Peter OFFICER, Cherry Hill, NJ (US); Michael J. TAMBURRI, Mt. Laurel, NJ (US)

(73) Assignee: SOLAREAMERICA, Malvern, PA (US)

(21) Appl. No.: 13/409,421

(22) Filed: Mar. 1, 2012

Related U.S. Application Data
(60) Provisional application No. 61/587,652, filed on Jan. 17, 2012.

(51) Int. Cl. H01L 31/048

(52) U.S. Cl. 136/251

(57) ABSTRACT

A system of mounting a plurality of arrays of photovoltaic devices includes a plurality of columns, a first array of photovoltaic devices arranged on a first platform, and a second array of photovoltaic devices arranged on a second platform. An upper edge of the first platform and an upper edge of the second platform are horizontally spaced-apart and each are vertically spaced-apart from the ground surface. A lower edge of the first platform and a lower edge of the second platform are horizontally spaced-apart and each is vertically spaced-apart from the ground surface. The second array of photovoltaic devices is arranged on the second platform a predetermined distance from the lower edge thereof which corresponds to a level of shading caused by the sun impacting the upper edge of the first platform to provide a maintenance area to access the second array of photovoltaic devices.

### CROSS-REFERENCE TO RELATED APPLICATIONS

The present application claims the benefit of U.S. Provisional Patent Application No. 61/587,652, filed Jan. 17, 2012 and entitled “Solar Canopy System and Method.”

### BACKGROUND OF THE INVENTION

The present invention is directed generally to a system and method for supporting at least one array of photovoltaic devices and, more particularly, to a system and method of supporting a plurality of arrays of photovoltaic devices at an angle above a ground surface. The system and method of the present invention maximizes the operating efficiency of the photovoltaic devices while allowing a relatively large number of arrays of photovoltaic devices to fit within a defined area.

Photovoltaic devices, which convert photons or light energy from the sun into usable electricity, are well known and widely used. Multiple photovoltaic devices are typically combined to form an array or module, commonly known as a solar panel. A large number of arrays is typically needed to produce a usable or economically beneficial amount of electricity. Therefore, it is desirable to mount arrays in locations or areas that can simultaneously serve different or alternative purposes. One such location is a conventional parking lot of an office building or shopping center, for example. At these locations, the ground surface can be used to park automobiles, for example, while a structure can be built above the parking lot and automobiles to support a plurality of the arrays of photovoltaic devices.

As shown in FIGS. 1A and 1B, commercialized prior art is generally limited to structures 110 that only cover certain portions of a parking lot 114 in which automobiles (none shown) are parked (i.e., parking spaces 118), as opposed to the portion(s) of the parking lot 114 in which automobiles are driven (i.e., driving lanes 116). In other words, certain prior art structures 110 do not utilize the drive aisles 116 or other additional available space to support or mount arrays of photovoltaic devices. The parking lot 114 of FIGS. 1A and 1B is positioned between two roads or highways 120.

Certain prior art designs are limited to covering only some parking spaces 118 of the parking lot 114 at least in part because the structures 110 are not able to effectively handle the stresses developed over relatively long distances. As such, commercialized prior art designs have generally been limited to spanning two parking bays, or a maximum span of approximately 30 to 40 feet. Commercialized prior art designs also support the arrays of photovoltaic devices generally parallel to the ground surface. Mounting the arrays in such a strictly horizontal position does not maximize the limited area in which the arrays of photovoltaic devices may be mounted and prevents the arrays from operating at an increased capacity. Positioning arrays at an angle on a horizontal base complicates the mounting hardware for the arrays.

Therefore, a need exists for a system and method for supporting one or more arrays of photovoltaic devices at an angle above a ground surface which allows continued use of the ground surface. Such a system is needed to maximize the limited or defined area in which to mount the arrays of photovoltaic devices and would increase the operating efficiency of the photovoltaic devices. In addition, a need exists for a system and method of mounting a plurality of arrays of photovoltaic devices in which wind or air flow is generally permitted to flow therethrough to create a structurally stable support system. The present invention accomplishes these present objectives.

### BRIEF SUMMARY OF THE INVENTION

Briefly stated, one aspect of the present invention is directed to a system of mounting a plurality of arrays of photovoltaic devices at an angle above a ground surface. A plurality of horizontally spaced-apart columns extend upwardly and generally perpendicularly to a ground surface. A first array of photovoltaic devices is arranged on a first platform supported vertically above the ground surface by at least four of the columns at an angle between two and twenty degrees with respect to the ground surface. The first platform has a lower edge and an opposing upper edge. A second array of photovoltaic devices is arranged on a second platform supported vertically above the ground surface at an angle between two and twenty degrees with respect to the ground surface by at least two of the columns supporting the first platform and at least two other columns. The second platform having a lower edge and an opposing upper edge. The upper edge of the first platform and the upper edge of the second platform being horizontally spaced-apart and each being vertically spaced-apart from the ground surface at a first distance. The lower edge of the first platform and the lower edge of the second platform being horizontally spaced-apart and each being vertically spaced-apart from the ground surface at a second distance. The first distance being greater then the first distance. The second array of photovoltaic devices being arranged on the second platform a predetermined distance from the lower edge thereof which corresponds to a level of shading caused by the sun impacting the upper edge of the first platform to provide a maintenance area to access the second array of photovoltaic devices.

In another aspect, the present invention is directed to a system of mounting one or more arrays of photovoltaic devices to a support structure above a ground surface. A support structure includes a plurality of spaced-apart columns extending perpendicularly to a plane defined by a ground surface. A plurality of first beams supported above the ground surface by the plurality of columns extend at an angle of less than ninety degrees and greater than zero degrees with respect to the plane defined by the ground surface. A platform is supported above the ground surface by the plurality of first beams. The platform generally covers the ground surface between the columns. A rail extends upwardly from the platform generally opposite to the plurality of first beams. The rail has a first end proximate the platform and an opposing second end. A first fastener extends through at least a portion of the first end of the rail and the platform and into at least a portion of one of the plurality of first beams. The system includes at least one array of photovoltaic devices attached to a base attached to a bottom surface of each photovoltaic device. A second fastener extends through the base and engages a portion of the second end of the rail to mount the array to the platform.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1A is a top perspective view of a system for supporting a plurality of arrays of photovoltaic devices according to the prior art;

FIG. 1B is a top perspective view of another system for support a plurality of arrays of photovoltaic devices according to the prior art;

FIG. 2 is a top perspective view of an entire system for supporting a plurality of arrays of photovoltaic devices according to a preferred embodiment of the present invention;

FIG. 3 is an enlarged exploded top perspective view of a portion of the entire system of FIG. 2;

FIG. 4 is a side elevation view of a portion of the entire system of FIG. 2, wherein three of the units shown in FIG. 3 are placed in series along a longitudinal axis of the system, with the plurality of arrays of photovoltaic devices and certain mounting hardware removed for clarity;

FIG. 5 is a greatly enlarged elevation view of a portion of the system taken along line 5-5 of FIG. 4, with at least a portion of one of the arrays of photovoltaic devices and the mounting hardware shown;

FIG. 6 is an enlarged top perspective and schematic view of a portion of the system of FIG. 2 from a viewpoint looking generally southwest;

FIG. 7 is an enlarged top perspective and schematic view of a portion of the system of FIG. 2 from a view point looking generally northeast; and

FIG. 8 is a front elevation and schematic view of a portion of the system shown in FIG. 2 from a viewpoint looking generally north, wherein an automobile is shown beneath the system and certain beams are removed for clarity.

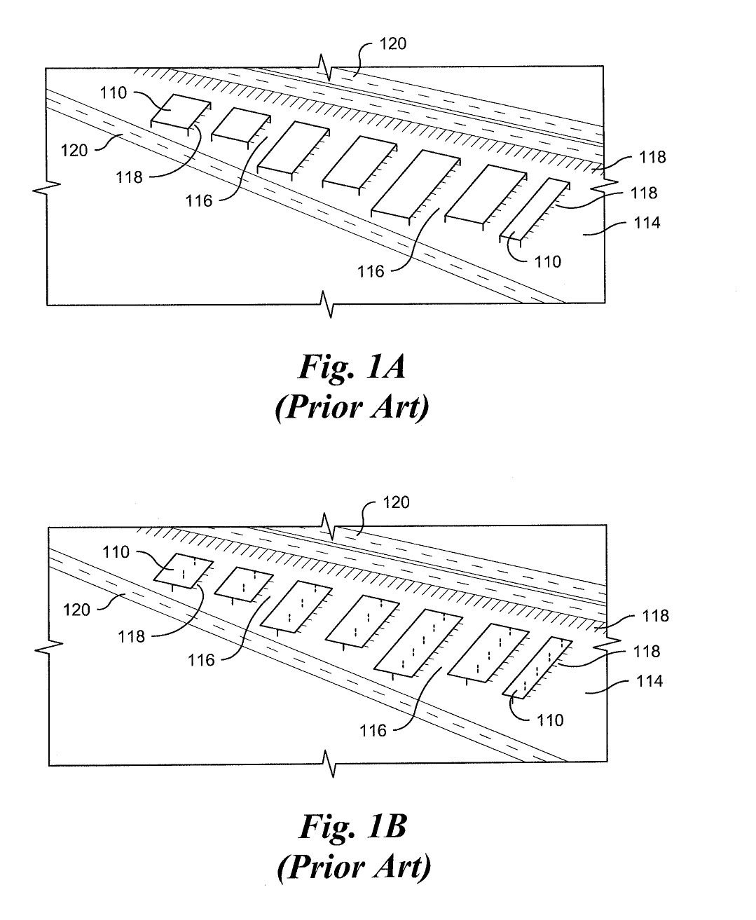

### DETAILED DESCRIPTION OF THE INVENTION

Certain terminology is used in the following description for convenience only and is not limiting. The words “right,” “left,” “lower,” “bottom,” “upper,” “top” and “front” designate directions in the drawings to which reference is made. The word “inwardly” refers to a direction toward the geometric center of the device, and designated parts thereof, in accordance with the present invention. Unless specifically set forth herein, the terms “a,” “an” and “the” are not limited to one element, but instead should be read as meaning “at least one.” The terminology includes the words noted above, derivatives thereof and words of similar import.

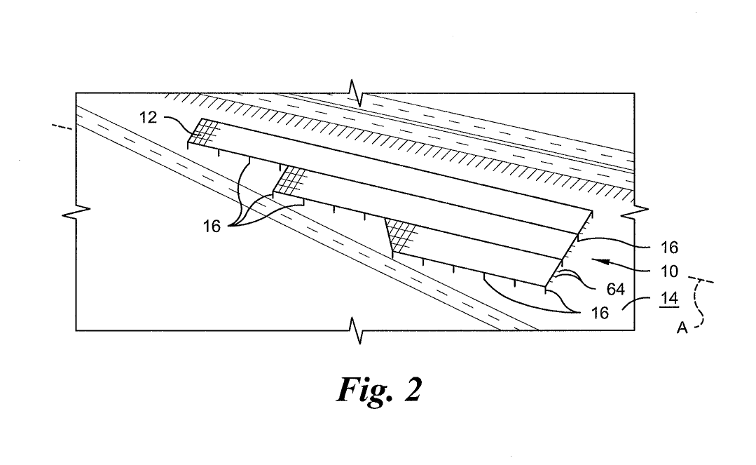

Referring to the drawings in detail, wherein like numerals indicate like elements throughout, FIGS. 2-8 show a system, generally designated 10, for supporting at least one and preferably a plurality of arrays or modules 12 of photovoltaic devices at an angle θ above a ground surface 14. This system 10 is generally a combination of columns, trusses, beams and the like, as described in detail below, that are combined to extend vertically upwardly from the ground surface 14 of a parking lot, for example. The system 10 supports the arrays 12 at the desired angle θ and in a desirable geographic orientation to generally maximize the number of arrays 12 capable of being positioned within a defined area of the parking lot and to generally maximize the operational efficiency (i.e., electrical production) of the photovoltaic devices that form each array 12. While it is preferred that the system 10 of the present invention is used in conjunction with or built on the ground surface 14 of a parking lot, the present invention is not so limited. For example, the system 10 of the present invention may be employed or built over an outdoor skating rink, an outdoor sports filed or other public space, a courtyard, or any other relatively large space in which it is desirable to employ a dual use.

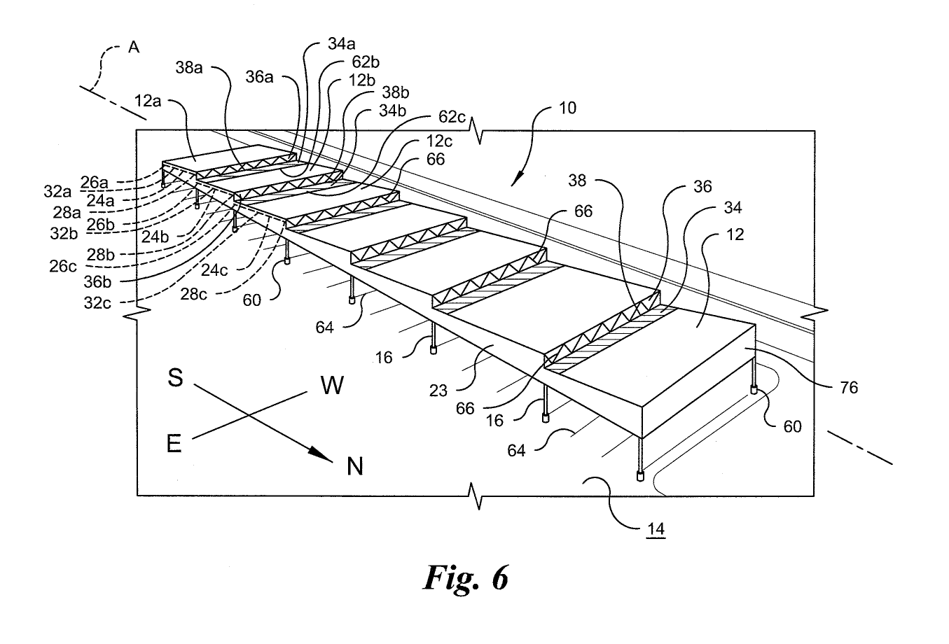

Referring to FIGS. 2-4 and 6-8, the system 10 preferably includes a plurality of horizontally spaced-apart columns 16 that extend vertically upwardly and generally perpendicularly to the ground surface 14. The columns 16 are preferably formed of a metallic material, such as steel, but the present invention is not so limited. For example, the columns 16 could be formed of concrete. It is preferred that at least two adjacent columns 16 of the plurality of columns 16 are horizontally spaced-apart at a sufficient distance to accommodate an automobile 58 (see FIG. 6) therethrough. The automobile 58 may be an eighteen wheel truck, a tractor-trailer, a sedan or a mini-van, for example.

The columns 16 preferably extend directly vertically upwardly from a portion of the lines 64 that outline or form the parking spaces of the parking lot. The present invention is not limited to any specific number or location of the columns 16, because the number and the location of the columns 16 is preferably dependent upon the total size or area of the parking lot, or at least the size of the portion of the parking lot in which it is desirable to support arrays 12 of photovoltaic devices. In other words, the system 10 of the present invention can be modified to accommodate and/or cover parking lots, or other support structures, of various sizes, shapes and/or geographic coordinates or locations on a planet, such as Earth.

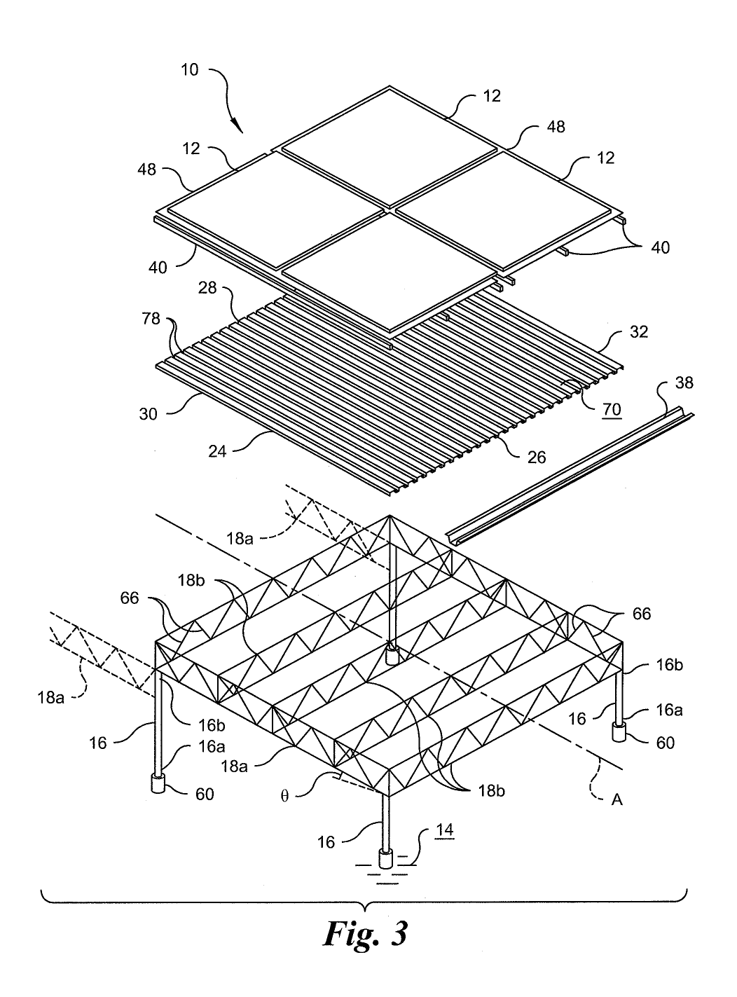

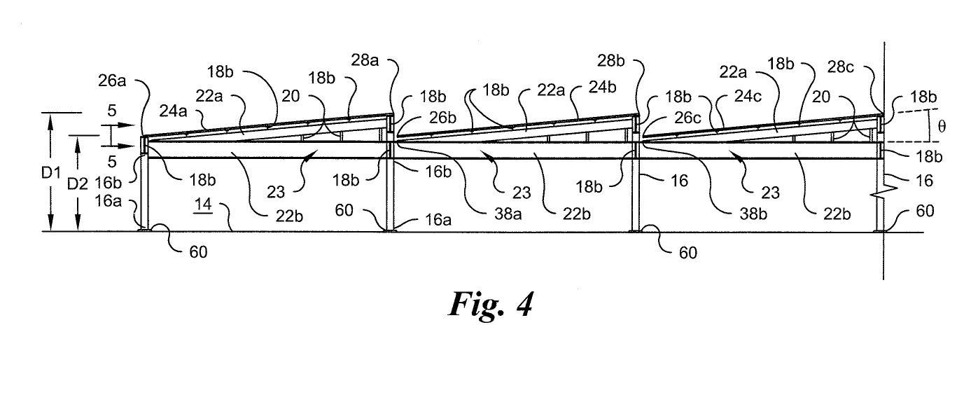

As shown in FIGS. 3 and 6-8, a lower end or portion 16a of each column 16 is preferably supported and/or surrounded by a base 60. The base 60 is preferably formed of concrete. In a preferred embodiment shown in FIGS. 3 and 6-8, each base 60 is generally cylindrical in shape, and an outer circumference or periphery of each base 60 is preferably greater than any one of the columns 16. However, the present invention is not so limited. For example, the base 60 could be omitted and each column 16 could be embedded in the ground surface 14. Alternatively, as shown in FIG. 4, the base 60 may simply be a relatively short or thin platform from which the columns 16 extend. It is preferred that the bases 60 provide structural support to the respective column 16.

Referring to FIGS. 3 and 4, the system 10 preferably includes a plurality of beams 18 supported vertically above the ground surface 14 by the plurality of columns 16. The beams 18 preferably extend at least in a direction of a longitudinal axis A of the system 10, but may also extend laterally across the system 10. For example, as shown in FIG. 3, the plurality of beams 18 preferably include longitudinally extending first beams 18a and laterally extending second beams 18b. All of the first beams 18a preferably extend generally, if not exactly, parallel to the longitudinal axis A of the system 10 and at least some or all of the second beams 18b preferably extend generally, if not exactly, perpendicularly to the longitudinal axis A of the system 10. Only portions of the second beams 18b are visible in FIG. 4, as the first beams 18a may be covered or generally not visible from a side elevation view in a preferred embodiment that includes a shell 23, as described in detail below.

It is preferred that a longitudinal axis of at least some or each of the plurality of second beams 18b extend generally, if not exactly, perpendicularly to each of the plurality of columns 16. It is also preferred that a longitudinal axis of each of the plurality of first beams 18a extend at the same angle θ, as described in detail below, at which the arrays 12 of photovoltaic devices extend with respect to the ground surface 14. Some of the plurality of second beams 18b may extend laterally across the system 10 such that some of the plurality of second beams 18b extend at the same angle θ, as described in detail below, at which the arrays 12 of photovoltaic devices extend with respect to the ground surface 14. In a preferred embodiment shown in FIG. 3, the system 10 includes at least two laterally spaced-apart first beams 18a on opposing lateral sides thereof and at least five longitudinally equidistantly spaced-apart second beams 18b. However, more or less beams 18 may be provided depending upon the structural requirements of the system 10 and/or the size and shape of the defined area of the parking lot. Further, while FIG. 3 shows each second beam 18b extending generally perpendicularly to the longitudinal axis A, the second beams 18b that are inwardly spaced-apart from an outer periphery of the system 10 may extend generally parallel to the longitudinal axis A and the first beams 18a. For example, the three middle second beams 18b in FIG. 3 may be modified to extend perpendicularly between the two second beams 18b that are positioned at the outer periphery of the system 10.

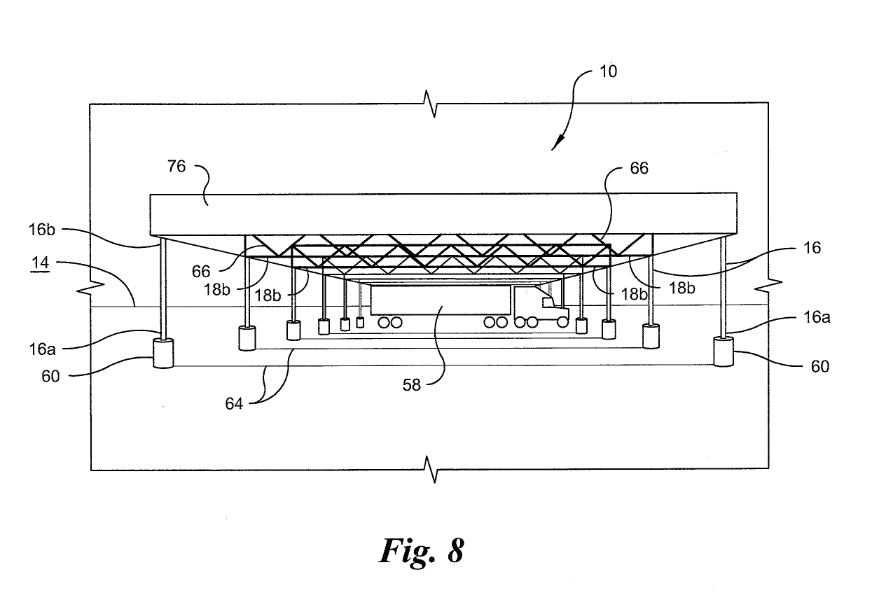

In a preferred embodiment, each beam 18 and preferably most if not all of the remaining components of the system 10 are formed of a metallic material, such as aluminum or galvanized steel. Each beam 18 may be in the form of an I-beam, or each beam 18 may be in the form of a plurality of angled braces arranged as a truss, such as the trusses 66 shown in FIGS. 3, 6 and 8. As shown in FIGS. 3 and 4, an upper end 16b of each column 16 may be positioned at one of two opposing ends of each beam 18. However, the columns 16 may be positioned longitudinally or laterally inwardly from the opposing ends of one or more of the beams 18, such that a predetermined portion of one or more of the beams 18 extend laterally or horizontally beyond each column 16 (see the front most portion of FIG. 8, for example). Certain of the beams 18 are not shown in FIG. 8 for the sake of clarity.

Referring specifically to FIG. 4, for aesthetic purposes, the system 10 preferably includes a shell 23 supported by and/or located proximate to the plurality of first beams 18a. The shell 23 is formed by at least two vertically spaced-apart first and second struts 22s and 22b preferably supported vertically above the ground surface 14 by a combination of the plurality of the columns 16 and first beams 18a. More preferably, the slope or slant of the first strut 22a with respect to the ground surface 14 is the same as the angle θ of the arrays 12 of photovoltaic devices. The second strut 22b extends generally horizontally across the columns 16 and generally parallel to the ground surface 14 to provide an aesthetically appealing look. Equidistantly spaced-apart bars 20 preferably extend generally vertically between the first and second struts 22a, 22b. As mentioned above, the shell 23 may be included and/or attached to the system 10 for aesthetic purposes only, but may also provide structural stability to the remaining elements of the system 10.

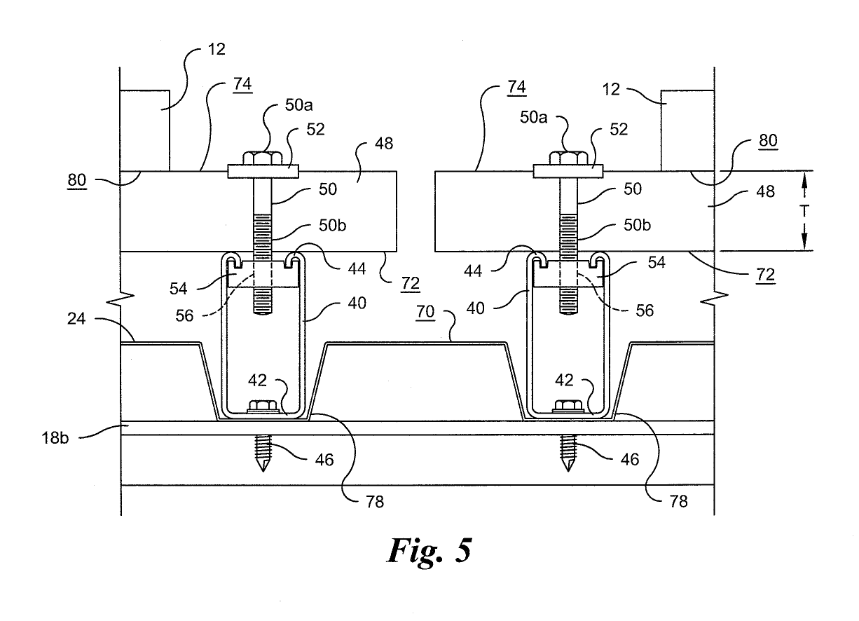

Referring FIGS. 3-5, the system 10 preferably includes a platform 24 supported above the ground surface 14 by at least the plurality of the beams 18 and the plurality of columns 16. It is preferred that the platform 24 extends at the same angle θ, as described in detail below, at which the arrays 12 of photovoltaic devices extend with respect to the ground surface 14. As shown in FIG. 3, the platform 24 preferably generally covers the ground surface 14 between the plurality of columns 16 that support the platform 24. The platform 24 preferably extends substantially continuously between the plurality of columns 16. Thus, the platform 24 acts as a roof above any ground surface 14 within the periphery of the plurality of column 16. As shown in FIGS. 3 and 5, it is preferred that the platform 24 is formed of sheet metal and is generally corrugated or has a generally undulating shape. The shape of the platform 24 increases the rigidity of the system 10 without increasing weight. In addition, the shape of the platform 24 provides depressions or channels 78 that direct rain water, for example, down the slope of the platform 24 and away from the ground surface 14 directly beneath the platform 24.

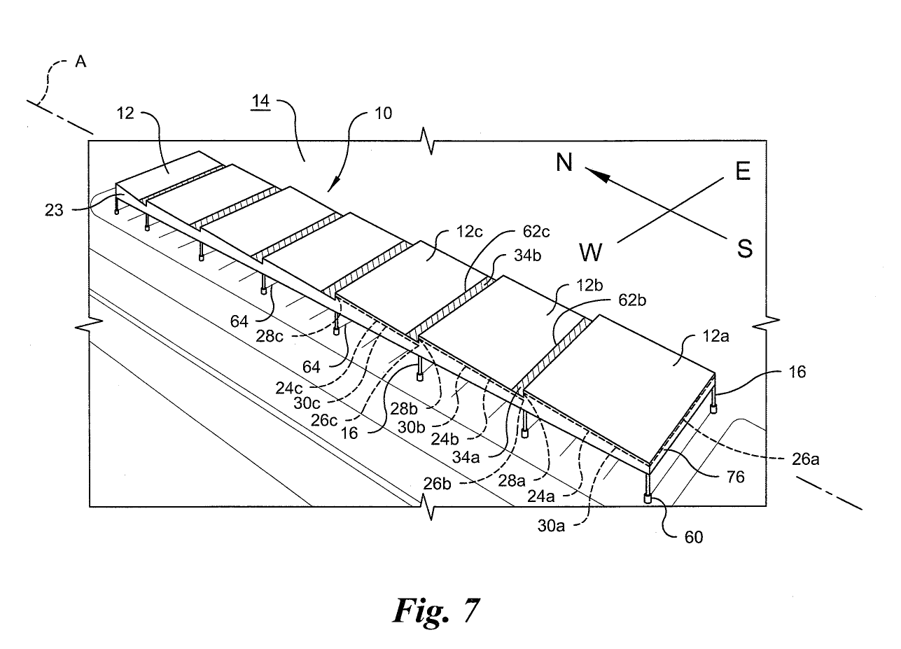

Referring to FIGS. 6 and 7, the present invention preferably includes a plurality of arrays 12 of photovoltaic devices. For example, a first array 12a of photovoltaic devices is preferably arranged on and/or vertically above a first platform 24a supported vertically above the ground surfaced 14 by at least four of the columns 16 and a plurality of the beams 18. It is preferred that the first array 12a is supported and/or positioned at the angle θ, which is preferably between two (2) and twenty (20) degrees with respect to the ground surface 14. More preferably, the angle θ is preferably between five (5) and fifteen (15) degrees with respect the ground surface 14. Thus, the first array 12a of photovoltaic devices preferably extends generally, if not exactly, parallel to the first platform 24a. As shown in FIG. 5, it is preferred that a bottom surface 80 of the first array 12a of photovoltaic devices is vertically spaced-apart a predetermined distance from a top surface 70 of the first platform 24a to form a gap therebetween, as described in more detail below.

A second array 12b of photovoltaic devices is preferably arranged on a second platform 24b supported vertically above the ground surface 14 at the angle θ. Thus, the second array 12b of photovoltaic devices preferably extends generally, if not exactly, parallel to the second platform 24b. As shown in FIG. 5, a bottom surface 80 of the second array 12b of photovoltaic devices is preferably vertically spaced-apart a predetermined distance from a top surface 70 of the second platform 24b to form a gap therebetween. Further, it is preferred that the first and second arrays 12a, 12b are mounted at the same slope or angle, but the present invention is not so limited. For example, the angle or slope of the first array 12a may be greater or less than the angle of the second array 12b. The second array 12b of photovoltaic devices is preferably supported by at least two of the columns 16 supporting the first platform 24a and at least two other or additional columns 16 of the plurality of columns 16.

As shown in FIG. 3, in a preferred embodiment each platform 24 preferably includes a first or lower edge 26, an opposing second or upper edge 28, a first or left side edge 30, and an opposing second or right side edge 32. More specifically, as shown in FIGS. 6 and 7, each of the first and second platforms 24a, 24b is generally square or rectangular in shape when viewed from above or below. Thus, each of the first and second platforms 24a, 24b preferably have a first or lower edge 26a, 26b, an opposing second or upper edge 28a, 28b, a first or left side edge 30a, 30b (shown in phantom in FIG. 7) and an opposing second or right side edge 32a, 32b (shown in phantom in FIG. 6). The top surface 70 of the first and second platforms 24a, 24b preferably extends between the first and second edges 26a, 26b, 28a, 28b, respectively, and between the first and second side edges 30a, 30b, 32a, 32b, respectively.

As shown in FIG. 4, the upper edge 28a of the first platform 24a and the upper edge 28b of the second platform 24b are preferably horizontally spaced-apart and each are vertically spaced-apart from the ground surface 14 at a first distance D1. Further, it is preferred that the lower edge 26a of the first platform 24a and the lower edge 26b of the second platform 24b are horizontally spaced-apart and each are vertically spaced-apart from the ground surface 14 at a second distance D2. It is preferred that the first distance D1 is greater than the second distance D2, which results in each of the first and second arrays 12a, 12b being angled with respect to the ground surface 14.

Referring again to FIGS. 6 and 7, it is preferred that the second array 12b of photovoltaic devices is arranged on or above the second platform 24b at a predetermined distance horizontally spaced-apart from the lower edge 26b thereof. More specifically, a bottom edge 62b of the second array 12b is horizontally spaced-apart from the lower edge 26b of the second platform 24b along the longitudinal axis A of the system 10. This predetermined distance preferably corresponds to a maximum level of shading caused by the sun impacting the upper edge 28a of the first platform 24a to provide a first maintenance area 34a to access the second array 12b of photovoltaic devices. In other words, if the largest shadow created by the upper edge 28a of the first platform 24a on the second platform 24b is calculated to be four feet along the longitudinal axis A of the system 10, then the first maintenance area 34a is designed to be four feet long along the longitudinal axis A of the system 10. Thus, the first maintenance area 34a is preferably defined by and/or located between the bottom edge 62b of the second array 12b and the lower edge 26b of the second platform 24b.

The first maintenance area 34a is preferably a platform that is sufficiently rigid to support the weight of one or more individuals thereon, which allows the individual(s) to perform any necessary maintenance to the second array 12b of photovoltaic devices. The first maintenance area 34a may be a solid platform that is placed on top of the portion of the second platform 24b that is not covered by the second array 12b of photovoltaic devices. Alternatively, the first maintenance area 34a may simply be the portion of the top surface 70 of the second platform 24b that is exposed or not covered by the second array 12b of photovoltaic devices. In the preferred embodiment, the first maintenance area 34a extends horizontally from the first side edge 30b of the second platform 24b to the opposing second side edge 32b thereof.

The combination of the angle θ of the first array 12a of photovoltaic devices and the positioning of the first platform 24a with respect to the second platform 24b (i.e., the first maintenance area 34a) minimizes the first platform 24a from blocking photons that could be received and/or absorbed by the second array 12b of photovoltaic devices. In other words, the upper edge 28a of the first platform 24a is sufficiently horizontally and vertically spaced-apart from the second array 12b of photovoltaic devices along the longitudinal axis A of the system 10 so that the first platform 24a minimizes blocking photons from hitting or entering the second array 12b of photovoltaic devices. As such, a maximum operating capacity of the second array 12b of photovoltaic devices is approached and/or achieved.

Referring specifically to FIG. 6, a first opening 36a is preferably formed between the upper edge 28a of the first platform 24a and the lower edge 26b of the second platform 24b. It is preferred that the first opening 36a extends at least vertically between the lower edge 26b of the second platform 24b and the upper edge 28a of the first platform 24a. It is also preferred that the first opening 36a extends generally from the first side edge 30a, 30b to the second side edge 32a, 32b of both the first and second platforms 24a, 24b, respectively. The first opening 36a preferably permits air flow between the first and second arrays 12a, 12b of photovoltaic devices. The first opening 36a is particularly beneficial in high wind applications or during windy or blustery conditions, such that the system 10 can withstand high winds, which also promotes cooling of the first and second arrays 12a, 12b even during less windy conditions.

Referring again to FIGS. 6 and 7, a third array 12c of photovoltaic devices is preferably arranged on a third platform 24c and is supported at the angle θ. Thus, the third array 12c of photovoltaic devices preferably extends generally, if not exactly, parallel to the third platform 24c. As shown in FIG. 5, a bottom surface 80 of the third array 12c of photovoltaic devices is preferably vertically spaced-apart a predetermined distance from a top surface 70 of the third platform 24c to form a gap therebetween. The third platform 24c is preferably supported vertically above the ground surface 14 by the two columns 16 that directly support the second platform 24b and at least two other or additional columns 16. Similar to the first and second platforms 24a, 24b, the third platform 24c preferably includes a first or lower edge 26c, an opposing second or upper edge 28c, a first or left side edge 30c (shown in phantom in FIG. 7), and an opposing second or right side edge 32c (shown in phantom in FIG. 6). A top surface of the third platforms 24c preferably extends between the first and second edges 26c, 28c, and between the first and second side edges 30c, 32c. The upper edge 28c of the third platform 24c is preferably horizontally spaced-apart along the longitudinal axis A of the system 10 from the upper edge 28a, 28b of each of the first and second platforms 24a, 24b, respectively.

As shown in FIG. 4, the upper edge 28c of the third platform 24c is preferably vertically spaced apart from the ground surface 14 at the first distance D1. The lower edge 26c of the third platform 24c is preferably spaced apart from the ground surface 14 at the second distance D2. The third array 12c of photovoltaic devices is preferably arranged on the third platform 24c at a predetermined distance horizontally spaced-apart from the lower edge 26c thereof. More specifically, as shown in FIGS. 6 and 7, a bottom edge 62c of the third array 12c is horizontally spaced-apart from the lower edge 26c of the third platform 24c along the longitudinal axis A of the system 10. The predetermined distance corresponds to a level of shading caused by the sun impacting the upper edge 28b of the second platform 24b to provide a second maintenance area 34b to access the third array 12c of photovoltaic devices. In other words, the second maintenance area 34b is preferably defined by and/or located between the bottom edge 62c of the third array 12c and the lower edge 26c of the third platform 24c.

Similar to the first maintenance area 34a, the second maintenance area 34b is preferably a platform that is sufficiently rigid to support the weight of one or more individuals thereon, which allows the individual(s) to perform any necessary maintenance to the second and/or third arrays 12b, 12c of photovoltaic devices. The second maintenance area 34b may be a solid platform that is placed on top of the portion of the third platform 24c that is not covered by the third array 12c of photovoltaic devices. Alternatively, the second maintenance area 34b may simply be the top portion 70 of the third platform 24c that is exposed or not covered by the third array 12c of photovoltaic devices. The second maintenance area 34b preferably extends horizontally from the first side edge 30c of the third platform 24c to the opposing second side edge 32c to the third platform 24c.

Referring again to FIG. 6, a second opening 36b is preferably formed between the upper edge 28b of the second platform 24b and the lower edge 26c of the third platform 24c. It is preferred that the second opening 36b extends at least vertically between the lower edge 26c of the third platform 24c and the upper edge 28b of the second platform 24b. It is also preferred that the second opening 36b extends generally from the first side edge 30b, 30c to the second side edge 32b, 32c of both the second and third platforms 24b, 24c, respectively. The second opening 36b preferably permits air flow between the second and third arrays 12b, 12c of photovoltaic devices. The second opening 36b is particularly beneficial in high wind applications or during windy or blustery conditions, such that the system 10 can withstand high winds, which also promotes cooling of the first and second arrays 12a, 12b even during less windy conditions.

The columns 16, beams 18, platform 24 and array 12 of photovoltaic devices of the system 10 shown in FIG. 3 are the base modular design of a preferred embodiment of the present invention. That is, the base modular design can be repeated as necessary in series (FIGS. 6 and 7) and in parallel (FIG. 2) to cover an existing ground surface 14. Stated differently, although only three separate arrays 12a, 12b, 12c and three separate platforms 24a, 24b, 24c are described in detail above, it is understood that the present invention may have more arrays 12 and corresponding platforms 24, maintenance areas 34 and openings 36 depending upon the predefined area of the parking lot. FIGS. 4, 6 and 7 show a plurality of arrays 12 and platforms 24 extending in a series. However, the system 10 of the present invention may be modified such that certain arrays 12 and certain platforms 24 are arranged in parallel as shown in FIG. 2, in addition or alternatively to being arranged in series.

Regardless of the number of arrays 12 and platforms 24, it is preferred that the platforms 24 and columns 16 are arranged such that the photovoltaic devices of each array 12 face substantially due south when the parking lot is located within a northern hemisphere of a planet, such as Earth. Such geographic orientation increases the operational efficiency of the photovoltaic devices. Ideally, the arrays 12 of photovoltaic devices would face directly south in a system 10 installed in the Northern Hemisphere of Earth. Conversely, in a parking lot in the Southern Hemisphere of Earth, it is preferred that each array 12 faces substantially due north.

As shown in FIGS. 6-8, one or more aesthetically pleasing end caps 76 may be placed on the exposed ends of the system 10. The end cap(s) 76 preferably generally enclose any gaps or open spacing between the second beams 18b and the columns 16 shown in FIG. 3. Each end cap 76 is schematically shown but is generally flat or planar to create an aesthetically-pleasing appearance for the system 10.

As shown in FIG. 3, the system 10 preferably includes one or more gutters 38. In a preferred embodiment, referring to FIG. 4, a first gutter 38a may be positioned along the first edge 26b of the second platform 24b. Furthermore, a second gutter 38b may be positioned along the first edge 26c of the third platform 24c. Each gutter 38 preferably collects and/or holds at least some debris, water or snow sliding and/or moving down the respective arrays 12 and platforms 24. Each gutter 38 preferably extends across the entire width of each platform 24 from the first side edge 30 to the second side edge 32 thereof. Each gutter 38 is preferably at least slightly sloped or slanted across the width of each platform 24 to direct any rainwater, for example, toward one of the columns 16. It is contemplated that each platform 24 may include one gutter 38, but the present invention is not so limited.

Referring to FIG. 3 and more specifically to FIG. 5, the system 10 includes mounting hardware to attached and/or mount the arrays 12 of photovoltaic devices to the respective platforms 24 and beams 18. More specifically, the mounting hardware includes a plurality of spaced-apart rails 40 that preferably extend upwardly from each platform 24 on the surface or side of the platform 24 generally opposite to the plurality of beams 18. In other words, the rails 40 extend upwardly from the top surface or side 70 of each platform 24. The rails 40 are preferably Unistrut rails, but the present invention is not so limited. The rails 40 preferably provide a receptacle to hold or mount the arrays 12 of photovoltaic devices, as described in detail below, and provide structural support to the system 10.

Although FIG. 5 shows the rails 40 being mounted or positioned within the channels 78 of the respective platform 24, the rails 40 may alternatively be mounted or positioned at or on one of the raised portions of the platform 24 adjacent to each channel 78. FIGS. 3 and 5 show the rails 40 extending generally parallel to the longitudinal axis A and laterally spaced-apart. In other words, each rail 40 may extend from the first edge 26 to the second edge 28 of the platform 24. However, the orientation of the rails 40 may be modified to extend generally perpendicularly to the longitudinal axis A and longitudinally spaced-apart, if desired for structural purposes. In this modified embodiment, each rail 40 would preferably extend from the first side edge 30 to the second side edge 32 of the platform 24.

Referring to FIG. 5, each rail 40 preferably has a first end 42 proximate or in abutting contact with the top surface 70 of the respective platform 24 and an opposing second end 44 extending upwardly therefrom. A first fastener 46 preferably extends through at least a portion of the first end 42 of each rails 40 and the platform 24 and into at least a portion of one of the plurality of beams 22. The first fastener 46 is preferably a bolt or screw, but the first fastener 46 is not so limited.

As shown in FIGS. 3 and 5, a base 48 is preferably attached to the bottom surface 80 of each array 12 of photovoltaic devices. Each base 48 is preferably generally flat or planer and has a predetermined thickness T. The base 48 provides an intermediate mounting structure between the platform 24 and the array of photovoltaic devices. A bottom surface 72 of the base 48 is preferably vertically spaced-apart at a predetermined distance from the top surface 70 of the respective platform 24 to promote airflow between the base 48 and the respective platform 24. A second fastener 50 preferably extends completely through the base 48 and engages a portion of the second end 44 of the rail 40 to mount the respective array 12 of photovoltaic devices to the respective platform 24. The second fastener 50 is preferably a bolt with a head 50a and a shaft 50b extending therefrom, but the present invention is not so limited. At least a portion of the shaft 50b of the second fastener 50 is preferably threaded. A washer 52 is preferably position between the head 50a of the second fastener 50 and a top surface 74 of the base 48. The second end 44 of the rail 40 may include or may be fixedly attached to a nut 54 with a preferably centrally positioned bore 56 therein. The bore 56 may be threaded to receive and engage at least a portion of the threaded shaft 50b of the second fastener 50. In an embodiment in which the nut 54 is a separate or removable structure from the second end 44 of the rail 40, at least a portion of the second end 44 of the rail 40, such as a free or exposed end, preferably extends into and/or engages a top surface of the nut 54. The above described mounting hardware allows the arrays 12 of photovoltaic devices to be removably mounted to the respective platform 24, in a secure, easily assembled manner that promotes or allows airflow therethrough.

Based upon the above description, it should be noted that the various components of the system 10 of the present invention are preferably mechanically coupled or fastened. Thus, it is preferred that there is no welding of any of the various components of the system 10 of the present invention. Employing mechanical coupling without any welding preserves the integrity of the material (preferably a metallic material) that forms the various components of the system 10. Stated differently, the mechanical coupling tends to cause little or no damage to any galvanized steel of the system 10.

The system 10 of the present invention allows for the use of a greater percentage of the area of a parking lot than systems of the prior art. Thus, the system 10 of the present invention provides additional area in which to mount or support arrays 12 of photovoltaic devices, thus converting significantly more solar energy into usable electrical energy. In fact, the present invention is capable of creating approximately 24-100% more or even greater than 100% more usable electrical energy than prior art systems as a result of the increased number of arrays 12 of photovoltaic devices and the improved angle and orientation of each array 12. The system 10 of the present invention also addresses and overcomes potential weather related complications, safety issues and liabilities. The present invention captures and redirects moisture or debris above the ground surface 14 beneath the system 10, thereby reducing or eliminating icicle formation, for example, and other hazardous conditions created by falling rain water, snow and/or debris in the area beneath the system 10.

As an example of the efficiency of a preferred embodiment of the system 10 of the present invention in comparison to prior art systems, a prior art system having 225 watt panels would have a maximum size of 215,550 watts with an estimated output of 231,800 kWh at 80% avg. irradiance. In contrast, the system 10 of the present invention installed in the same available area using the same panels would have a maximum size of 406,350 watts with an estimated output of 462,467 kWh at 80% avg. irradiance. Accordingly, the system 10 of the present invention, when compared to the best case scenarios utilizing prior art solar canopy systems, may provide an additional 150,800 watts (155.8 kW), or an additional 230,667 kWh of solar electricity a year. The improvement in energy produced on an annual basis is nearly 50%.

It will be appreciated by those skilled in the art that changes could be made to the embodiments described above without departing from the broad inventive concept thereof. The system 10 may be engineered and/or designed to conform to standard parking area dimensions and layouts. The system 10 is sufficiently flexible in design requirements to meet or conform to any potential parking lot irregularities. It is understood, therefore, that this invention is not limited to the particular embodiments disclosed, but it is intended to cover modifications within the spirit and scope of the present invention as defined by the appended claims.

We claim:

1. A system for supporting a plurality of arrays of photovoltaic devices at an angle above a ground surface, the system comprising:
a plurality of horizontally spaced-apart columns extending upwardly and generally perpendicularly to a ground surface;
a first array of photovoltaic devices arranged on a first platform supported vertically above the ground surface by at least four of the columns at an angle between two and twenty degrees with respect to the ground surface, the first platform having a lower edge and an opposing upper edge;
a second array of photovoltaic devices arranged on a second platform supported vertically above the ground surface at an angle between two and twenty degrees with respect to the ground surface by at least two of the columns supporting the first platform and at least two other columns, the second platform having a lower edge and an opposing upper edge, the upper edge of the first platform and the upper edge of the second platform being horizontally spaced-apart and each being vertically spaced-apart from the ground surface at a first distance, the lower edge of the first platform and the lower edge of the second platform being horizontally spaced-apart and each being vertically spaced-apart from the ground surface at a second distance, the first distance being greater than the second distance, the second array of photovoltaic devices being arranged on the second platform a predetermined distance from the lower edge thereof which corresponds to a level of shading caused by the sun impacting the upper edge of the first platform to provide a first maintenance area to access at least the second array of photovoltaic devices.

2. The system according to claim 1, wherein the first maintenance area of the second platform extends horizontally from a first side edge of the second platform to an opposing second side edge of the second platform.

3. The system for according to claim 1, further comprising:
a third array of photovoltaic devices arranged on a third platform supported at an angle between two and twenty degrees with respect to the ground surface vertically above the ground surface by the two columns directly supporting the second platform and at least two other columns, the third platform having a lower edge and an upper edge, the upper edge of the third platform being horizontally spaced apart from the upper edge of each of the first and second platforms, the upper edge of the third platform being vertically spaced-apart from the ground surface at the first distance, the lower edge of the third platform being vertically spaced-apart from the ground surface at the second distance, the third array of photovoltaic devices being arranged on the third platform a predetermined distance from the lower edge thereof which corresponds to a level of shading caused by the sun impacting the upper edge of the second platform to provide a second maintenance area to access the third array of photovoltaic devices.

4. The system according to claim 3, wherein the first maintenance area extends horizontally from a first side edge of the second platform to an opposing second side edge of the second platform and the second maintenance area extends horizontally from a first side edge of the third platform to an opposing second side edge of the third platform.

5. The system according to claim 1, wherein at least two adjacent columns of the plurality of columns are horizontally spaced-apart at a sufficient distance to accommodate an automobile therethrough.

6. The system according to claim 1, wherein the angle of the first array of photovoltaic devices and the positioning of the first platform with respect to the second platform minimizes the first platform from blocking photons from the second array of photovoltaic devices.

7. The system according to claim 1, further comprising:
a vertically-extending first opening formed between the upper edge of the first platform and the lower edge of the second platform to permit airflow between the respective arrays of photovoltaic devices.

8. The system according to claim 3, further comprising:
a vertically-extending second opening formed between the upper edge of the second platform and the lower edge of the third platform to permit airflow between the respective arrays of photovoltaic devices.

9. The system according to claim 8, further comprising:
a gutter positioned along a lower edge of the second platform; and
a gutter positioned along a lower edge of the third platform.

10. The system according to claim 1, wherein the angle of each platform is between five and fifteen degrees.

11. The system according to claim 1, wherein the platforms and columns are arranged such that photovoltaic devices of each array face substantially due south.

12. The system according to claim 1, further comprising:
a plurality of beams supported above the ground surface by the plurality of columns supporting the first platform, at least some of the plurality of beams extending generally perpendicularly to each of the plurality of columns supporting the first platform; and
a plurality of bars supported by the plurality of columns and extending perpendicularly to at least some of the plurality of beams.

13. The system according to claim 1, wherein the first and second arrays of photovoltaic devices extend generally parallel to the first and second platforms, respectively, and wherein the first and second arrays of photovoltaic devices are spaced-apart vertically from the first and second platforms, respectively, a predetermined distance such that a gap is located therebetween.

14. A system for mounting one or more arrays of photovoltaic devices to a support structure above a ground surface, the system comprising:
a support structure including:
a plurality of spaced-apart columns extending generally perpendicularly to a plane defined by a ground surface;
a plurality of first beams supported above the ground surface by the plurality of columns, the plurality of first beams extending at an angle of less than ninety degrees and greater than zero degrees with respect to the plane defined by the ground surface;
a platform supported above the ground surface by the plurality of first beams, the platform generally covering the ground surface between the plurality of columns;
a rail extending upwardly from the platform generally opposite to the plurality of first beams, the rail having a first end proximate the platform and an opposing second end; and
a first fastener extending through at least a portion of the first end of the rail and the platform and into at least a portion of one of the plurality of first beams;
at least one array of photovoltaic devices; and
a base attached to a bottom surface of each array of photovoltaic devices,
wherein a second fastener extends through the base and engages a portion of the second end of the rail to mount the array to the platform.

15. The system according to claim 14, further comprising:
a washer positioned between a head of the second fastener and a top surface of the base; and
a nut including a groove therein, at least a portion of the second end of the rail extending into at least a portion of the groove of the nut.

16. The system according to claim 14, wherein the platform is corrugated, and wherein a bottom surface of the base is spaced-apart a predetermined distance from a top surface of the platform to promote airflow between the base and the platform.

17. The system according to claim 14, wherein a top surface of the array is angled between two and twenty degrees with respect to the plane defined by the ground surface, and wherein the top surface of the array faces substantially due south.

18. The system according to claim 14, further comprising:
a gutter positioned along a lower edge of the platform.
